(19) United States
(12) Patent Application Publication
(10) Pub. No.: US 2002/0063273 A1
(43) Pub. Date: May 30, 2002

(54) Semiconductor device and method of fabricating the same

(75) Inventors: Kenichi Ooto, Hyogo (JP); Yoshinori Tanaka, Hyogo (JP)

Correspondence Address: McDERMOTT, WILL & EMERY, 600 13th Street, N.W., Washington, DC, 20005-3096, US

(73) Assignee: MITSUBISHI DENKI KABUSHIKI KAISHA

(21) Appl. No.: 09/836,243

(22) Filed: Apr. 18, 2001

(30) Foreign Application Priority Data
Nov. 28, 2000 (JP) 2000-361316(P)

(51) Int. Cl. H01L 27/108; H01L 29/76; H01L 29/94; H01L 31/119; H01L 21/8242; H01L 21/20; H01L 21/4763

(52) U.S. Cl. 257/296; 257/908; 257/300; 438/243; 438/386; 438/637

(57) ABSTRACT

Disclosed is a method of fabricating a semiconductor device improved to increase a transfer margin of a hole. A first insulating interlayer is formed on a semiconductor substrate so as to cover a memory cell region and a peripheral circuit region. The surface of the first insulating interlayer is polished. A second insulating interlayer is formed on the first insulating interlayer. A hole penetrating the first and second insulating interlayers is opened, and a cylindrical capacitor is formed in the hole.

### BACKGROUND OF THE INVENTION

1. Field of the Invention

The present invention generally relates to a semiconductor device and, more particularly, to a semiconductor device improved to increase the capacity of a capacitor. The invention also relates to a method of fabricating a semiconductor device improved to increase a transfer margin in a lithography process.

2. Description of the Background Art

Conventionally, a cylindrical capacitor is employed to increase the capacity. A method of fabricating a conventional semiconductor device having a cylindrical capacitor will be described with reference to the drawings.

Referring to FIG. 9, on a p-type substrate 100, an isolation oxide film 1, a gate electrode 2, and a side wall spacer 3 are formed, and desired ion implantation is carried out, thereby forming a transistor. In the drawing, reference numeral 4 denotes an insulating film. An insulating interlayer 6 is formed on the substrate 100 so as to cover the transistor. In the insulating interlayer 6, a contact hole 50 for exposing a diffusion layer is formed, and a conductive pad 5 is formed in the contact hole 50.

Referring to FIG. 10, an insulating interlayer 7 is formed on the insulating interlayer 6. A bit line 8, a side wall spacer 9, and an insulating film 10 are formed. On the insulating interlayer 7, an insulating interlayer 11 is formed. A storage node contact 12 is formed in the insulating interlayers 11 and 7 so as to be on the conductive pad 5.

Referring to FIG. 11, on the insulating interlayer 11, an insulating interlayer 13 made by an SiN film is deposited to 50 to 100 nm so as to cover the storage contact 12. On the insulating interlayer 13, an insulating interlayer 14 is deposited to 1400 nm to 1700 nm. As the insulating interlayer 14, in order to decrease the amount of heat applied to the transistor, to increase an etching rate, and to suppress a film decreasing amount of a resist when a hole is opened, a low-temperature oxide film in which B or P is doped is generally used.

In the conventional technique, reflow is performed to reduce a step. For reasons such as reduction in the amount of heat applied to the transistor and use of a metal wire as the bit line 8, heat treatment at 800° C. or higher for 30 minutes or longer cannot be performed, so that flatness cannot be assured.

After that, the insulating interlayer 15 is deposited to 100 nm to 200 nm on the insulating interlayer 14. As the insulating interlayer 15, an insulating film of a low etching rate is used.

The reasons why the process of forming the insulating interlayer 15 is indispensable in the conventional method will now be described. FIG. 12 is a diagram showing problems which occur when the process of forming the insulating interlayer 15 is omitted.

Referring to FIG. 12, since the reflow temperature for the insulating interlayer 14 is low, a wet etching rate is high. Consequently, the tip E of the cylindrical capacitor 16 is projected from the surface of the insulating interlayer 14. The projected portion is broken, flown, and adhered onto the insulating interlayer for isolating devices. A short circuit is caused, and a problem such that the yield deteriorates occurs. In order to prevent occurrence of such a problem, the process of forming the insulating interlayer 15 is indispensable in the processes shown in FIG. 11.

Referring now to FIGS. 11 and 13, contact holes 161 for exposing the surface of the storage node contact 12, which penetrate the insulating interlayers 15, 14, and 13 are formed. A conductive layer 16a serving as a lower electrode of the capacitor is deposited so as to cover the side walls and the bottom face of each of the contact holes 161.

In FIG. 14, when the conductive layer 16a used for the lower electrode of the capacitor is made of polysilicon, in order to obtain sufficient capacity of the capacitor, the surface of the conductive layer 16a is made rough (rough surface).

Referring to FIGS. 14 and 15, the contact hole 161 is filled with a protective material (not shown), etch back is carried out, and the protective material is removed, thereby finishing the patterning of the lower electrode 16 of the cylindrical capacitor.

Referring to FIG. 16, a capacitor insulating film 17 is deposited over the substrate 100 so as to cover the cylindrical capacitor lower electrode 16. A cell plate electrode 18 to be buried in the contact hole 161 is formed so as to be in contact with the capacitor lower electrode 16 via the capacitor insulating film 17. After that, so as to cover the cell plate electrode 18, an insulating interlayer 19 is deposited on the insulating interlayer 15. The surface of the insulating interlayer 19 is polished by CMP (Chemical Mechanical Polishing) and, after that, an insulating interlayer 20 is deposited on the insulating interlayer 19.

A contact hole 21 for exposing the surface of the bit line 8, which penetrates the insulating interlayers 20, 19, 15, 14, 13, 11, and 10 is formed. After that, a conductive member 211 is buried in the contact hole 21, thereby completing a semiconductor including the cylindrical capacitor.

The conventional method of fabricating the semiconductor device including the cylindrical capacitor constructed as described above has the following problems.

First, in FIG. 11, a difference between the highest position and the lowest position of the surface of the insulating interlayer 14 is 300 nm to 500 nm. When the contact hole is opened in the insulating interlayer 14, there is a problem such that a transfer margin of the contact hole decreases.

A second problem is as follows. FIG. 17 is an enlarged view of the portion of a memory cell block end A shown in FIG. 11. The problem relates to the case where a contact hole is opened in the stepped portion. In FIG. 17, reference numeral 22 denotes a resist. The thickness of the insulating interlayer 15 etched to open the contact hole is (a). However, in the stepped portion, the thickness of the insulating interlayer 15 to be etched is as thick as (b). Consequently, at the memory cell block end A, poor opening occurs, and a problem such that it deteriorates the yield occurs.

Third, referring to FIG. 15, at the time of performing over-etching to prevent occurrence of a polysilicon residue in a step portion B, the tip of the lower electrode 16 is also etched and is recessed by 50 to 100 nm. A problem such that the capacity decreases and, moreover, a refresh characteristic deteriorates arises.

Fourth, referring to FIG. 13, since a film of a low etching rate is used as the insulating interlayer 15, when the contact hole 161 is opened, the insulating interlayer 15 is residual. When there is a residue of the insulating interlayer 15, at the time of opening a contact hole of a high aspect ratio, etching is difficult. Consequently, poor opening occurs and there is a problem such that the yield deteriorates.

### SUMMARY OF THE INVENTION

The present invention has been achieved to solve the problems as described above, and its object is to provide a method of fabricating a semiconductor device improved to increase a transfer margin in a photograph process.

Another object of the invention is to provide a method of fabricating a semiconductor device improved to prevent poor opening in an inclined portion of a step.

Further another object of the invention is to provide a method of fabricating a semiconductor device improved to increase the capacity of a capacitor by preventing the tip of a cylindrical capacitor from being recessed at the time of etch back performed to form the cylindrical capacitor.

Further another object of the invention is to provide a method of fabricating a semiconductor device improved to prevent poor opening of a contact hole.

Further another object of the invention is to provide a semiconductor device obtained by such a fabricating method.

A semiconductor device according to a first aspect of the invention has a semiconductor substrate having a memory cell region in which a memory cell is to be formed and a peripheral circuit region in which a peripheral circuit is to be formed. A first insulating interlayer is provided on the semiconductor substrate so as to cover the memory cell region and the peripheral circuit region. A second insulating interlayer is provided on the first insulating interlayer. An interface between the first and second insulating interlayers is parallel to the surface of the semiconductor substrate.

In a preferred embodiment of the invention, the second insulating interlayer is formed by an antireflection film.

In a method of fabricating a semiconductor device according to a second aspect of the invention, a semiconductor substrate having a memory cell region in which a memory cell is to be formed and a peripheral circuit region in which a peripheral circuit is to be formed is prepared. A first insulating interlayer is formed on the semiconductor substrate so as to cover the memory cell region and the peripheral circuit region. The surface of the first insulating interlayer is polished. A second insulating interlayer is formed on the first insulating interlayer. A hole penetrating the first and second insulating interlayers is formed in the memory cell region and a cylindrical capacitor is formed in the hole.

According to a preferred embodiment of the invention, an antireflection film is used as the second insulating interlayer.

According to a more preferred embodiment of the invention, the step of forming the cylindrical capacitor includes:

a step of forming a hole penetrating the first and second insulating interlayers in the memory cell region. A first conductive layer for forming a lower electrode of a capacitor is formed on the second insulating interlayer so as to cover side walls and a bottom face of the hole. A capacitor lower electrode is formed by etching back the first conductive layer to expose a surface of the second insulating interlayer. The surface of the capacitor lower electrode is covered with a capacitor insulating film. A second conductive layer for forming a cell plate electrode, which is buried in the hole so as to be in contact with the capacitor lower electrode via the capacitor insulating film is formed. A cell plate electrode is formed by patterning the second conductive layer.

According to a preferred embodiment of the invention, a silicon oxide film to which B or P is doped is used as the first insulating interlayer, and an SiN film is used as the second insulating interlayer.

In a method of fabricating a semiconductor device according to a third aspect of the invention, first, a semiconductor substrate having a memory cell region in which a memory cell is to be formed and a peripheral circuit region in which a peripheral circuit is to be formed is prepared. A first insulating interlayer is formed on the semiconductor substrate so as to cover the memory cell region and the peripheral circuit region. The surface of the first insulating interlayer is polished. A second insulating interlayer is formed on the first insulating interlayer. In the memory cell region, a hole penetrating the first and second insulating interlayers is formed. A first conductive layer for forming a capacitor lower electrode is formed on the second insulating interlayer so as to cover side walls and a bottom face of the hole. The first conductive layer is etched back to expose the surface of the second insulating interlayer, thereby forming a capacitor lower electrode. The surface of the capacitor lower electrode is covered with a capacitor insulating film. A second conductive layer for forming a cell plate electrode, which is buried in the hole so as to be in contact with the capacitor lower electrode via the capacitor insulating film is formed. A cell plate electrode is formed by selectively etching the second conductive layer and the second insulating interlayer in a portion where the cell plate electrode is not formed is removed by etching. A third insulating interlayer is formed over the semiconductor substrate so as to cover the cell plate electrode.

In a preferred embodiment of the invention, a silicon oxide film to which B and P is doped is used as the first insulating interlayer, and an SiN film is used as the second insulating interlayer.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a cross section of a semiconductor device in a first process in a method of fabricating a semiconductor device according to a first embodiment;

FIG. 2 is a cross section of the semiconductor device in a second process in the method of fabricating the semiconductor device according to the first embodiment;

FIG. 3 is a cross section of the semiconductor device in a third process in the method of fabricating the semiconductor device according to the first embodiment;

FIG. 4 is a cross section of the semiconductor device in a fourth process in the method of fabricating the semiconductor device according to the first embodiment;

FIG. 5 is a cross section of the semiconductor device in a fifth process in the method of fabricating the semiconductor device according to the first embodiment;

FIG. 6 is a cross section of the semiconductor device in a sixth process in the method of fabricating the semiconductor device according to the first embodiment;

FIG. 7 is a cross section of a semiconductor device in a first process in a method of fabricating a semiconductor device according to a third embodiment;

FIG. 8 is a cross section of the semiconductor device in a second process in the method of fabricating the semiconductor device according to the third embodiment;

FIG. 9 is a cross section of a semiconductor device in a first process of a conventional semiconductor device fabricating method;

FIG. 10 is a cross section of the semiconductor device in a second process of the conventional semiconductor device fabricating method;

FIG. 11 is a cross section of the semiconductor device in a third process of the conventional semiconductor device fabricating method;

FIG. 12 is a diagram showing problems which occur when the process of forming an insulating interlayer 15 is omitted in FIG. 11;

FIG. 13 is a cross section of the semiconductor device in a fourth process of the conventional semiconductor device fabricating method;

FIG. 14 is a cross section of the semiconductor device in a fifth process of the conventional semiconductor device fabricating method;

FIG. 15 is a cross section of the semiconductor device in a sixth process of the conventional semiconductor device fabricating method;

FIG. 16 is a cross section of the semiconductor device in a seventh process of the conventional semiconductor device fabricating method; and

FIG. 17 is a diagram showing problems of the conventional semiconductor device fabricating method.

### DESCRIPTION OF THE PREFERRED EMBODIMENTS

Embodiments of the invention will be described hereinbelow with reference to the drawings.

First Embodiment

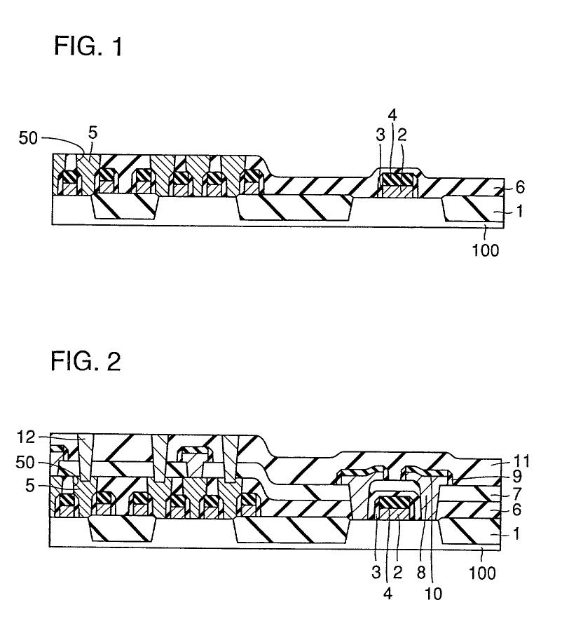

Referring to FIG. 1, on a p-type substrate 100, an isolation oxide film 1, a gate electrode 2, and a side wall spacer 3 are formed, and desired ion implantation is carried out, thereby forming a transistor. In the drawing, reference numeral 4 denotes an insulating film. An insulating interlayer 6 is formed on the substrate 100 so as to cover the transistor. In the insulating interlayer 6, a contact hole 50 for exposing a diffusion layer is formed, and a conductive pad 5 is formed in the contact hole 50.

Referring to FIG. 2, an insulating interlayer 7 is formed on the insulating interlayer 6. A bit line 8, a side wall spacer 9, and an insulating film 10 are formed. On the insulating interlayer 7, an insulating interlayer 11 is formed. A storage node contact 12 is formed so as to be overlap on the conductive pad 5.

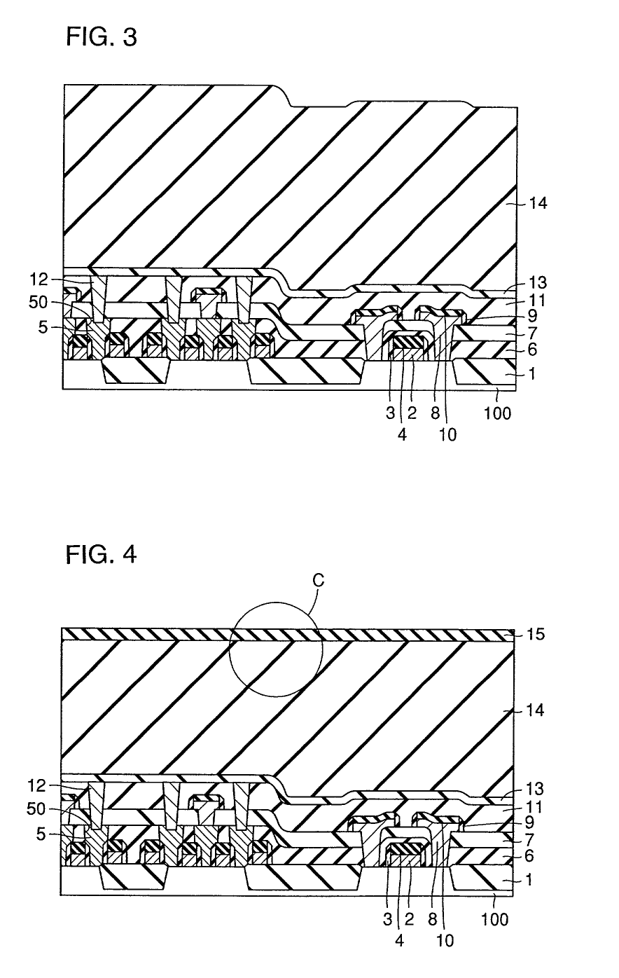

Referring to FIG. 3, on the insulating interlayer 11, an insulating interlayer 13 made by an SiN film is deposited to 50 to 100 nm. On the insulating interlayer 13, an insulating interlayer 14 is deposited to 170 nm to 200 nm. After that, the insulating interlayer 14 is polished by CMP by 400 to 700 nm (not shown), thereby planarizing the surface of the insulating interlayer 14.

Referring to FIG. 4, on the planarized insulating interlayer 14, an insulating interlayer 15 is deposited to 100 nm to 200 nm.

In the embodiment, a step in the surface of the insulating interlayer 15 can be reduced, so that the transfer margin of the hole is improved.

Since the interface between the insulating interlayers 14 and 15 is in parallel with the substrate in a portion from the memory cell portion to a peripheral circuit portion (in a portion C), the step can be reduced. By referring to FIG. 17, since the thickness (b) becomes close to the thickness (a), poor opening in etching can be prevented.

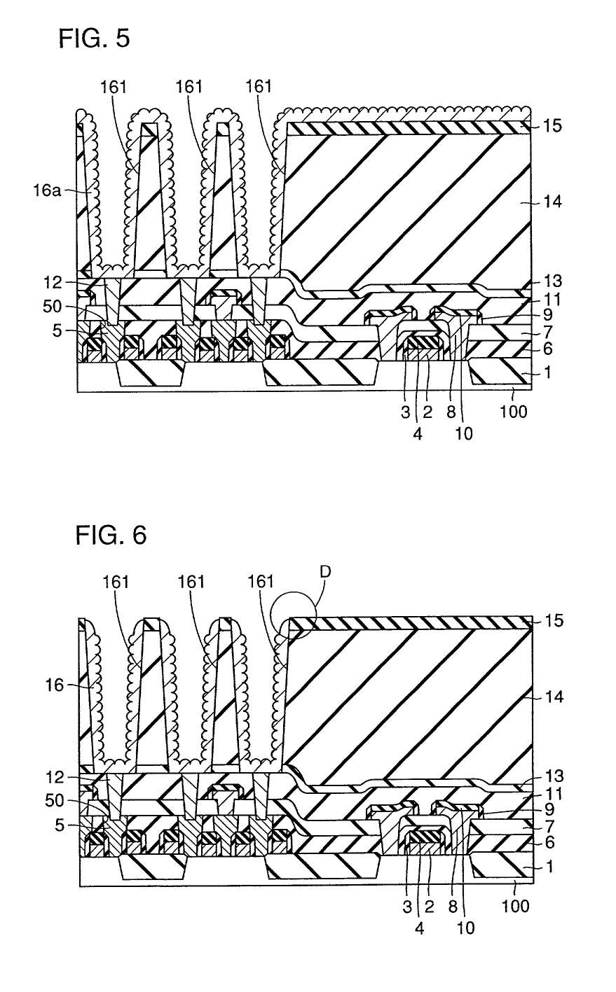

Referring now to FIG. 5, contact holes 161 for exposing the surface of the storage node contact 12, which penetrate the insulating interlayers 15, 14, and 13 are formed. A first conductive layer 16a for forming a capacitor lower electrode is formed on the insulating interlayer 15 so as to cover the side walls and the bottom face of each of the contact holes 161. After that, the surface of the first conductive layer 16a is made rough.

Referring to FIGS. 5 and 6, the first conductive layer 16a is etched back to expose the surface of the insulating interlayer 15, thereby forming a lower electrode 16 of the capacitor.

According to the invention, no step exists in the surface of the insulating interlayer 15. Consequently, even when the conductive layer 16a is etched back, a residue of the conductive layer 16a does not occur. Thus, the over-etch amount in the etch back can be decreased, a recess at the tip D of the cylindrical capacitor lower electrode 16 is suppressed, and reduction in the capacity of the capacitor can be suppressed.

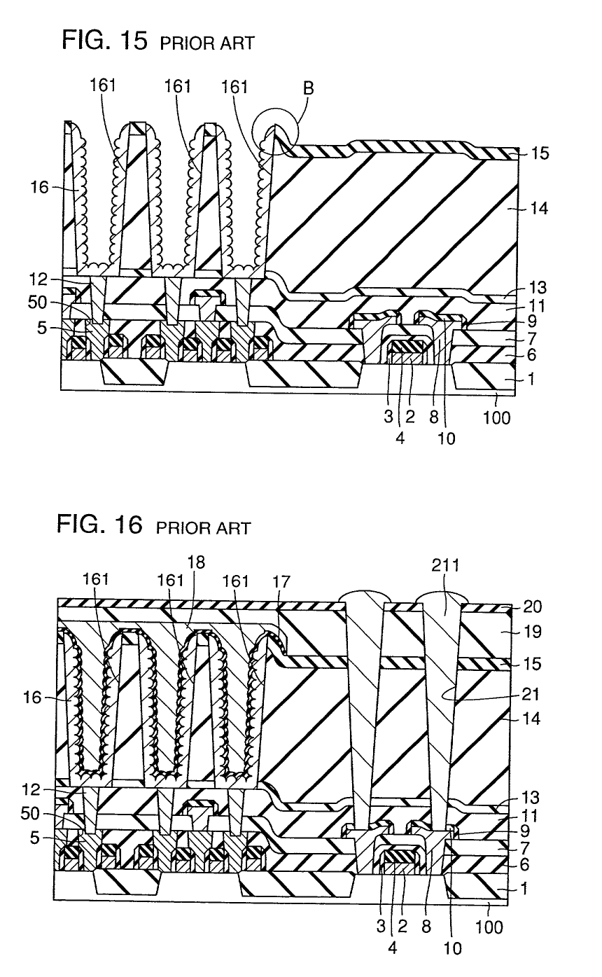

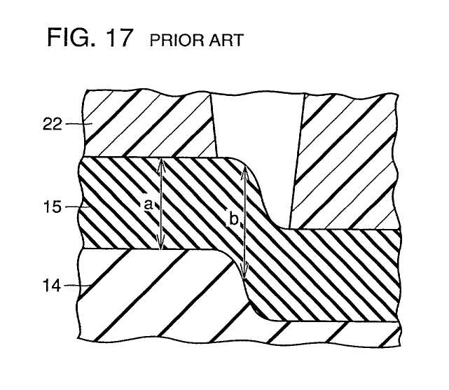

After that, by performing processes similar to conventional ones shown in FIGS. 15 and 16, a semiconductor device is completed.

Second Embodiment

The processes of a fabricating method according to a second embodiment are similar to those of the first embodiment shown in FIGS. 1 to 6. In the second embodiment, however, an insulative antireflection film is used as the insulating interlayer 15. According to the second embodiment, since the antireflection film is used as the insulating interlayer 15, a transfer margin is improved in the photography process for forming the storage node.

Third Embodiment

First, processes similar to those shown in FIGS. 1 to 6 are performed.

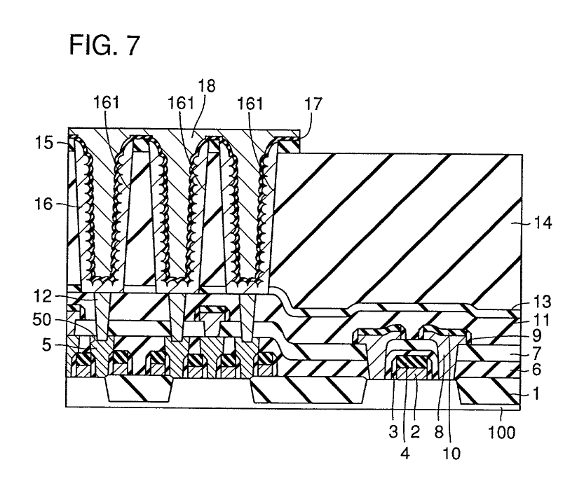

After that, referring to FIG. 7, a capacitor insulating film 17 is deposited and a cell plate 18 is formed. At the time of forming the capacitor insulating film 17 and the cell plate 18, the insulating interlayer 15 is removed by over-etching.

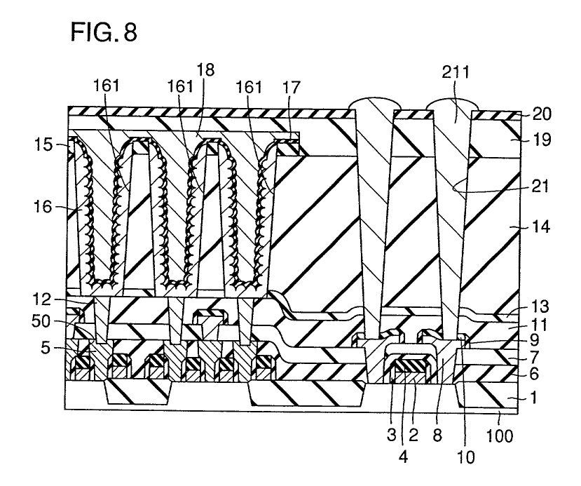

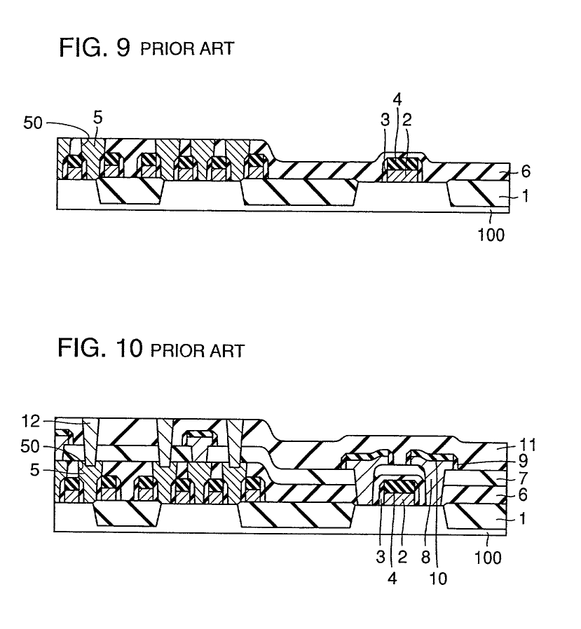

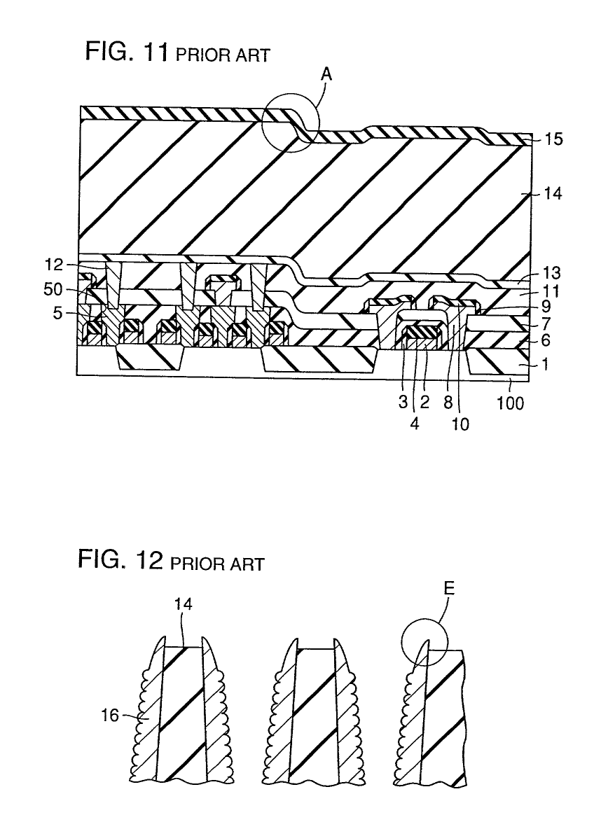

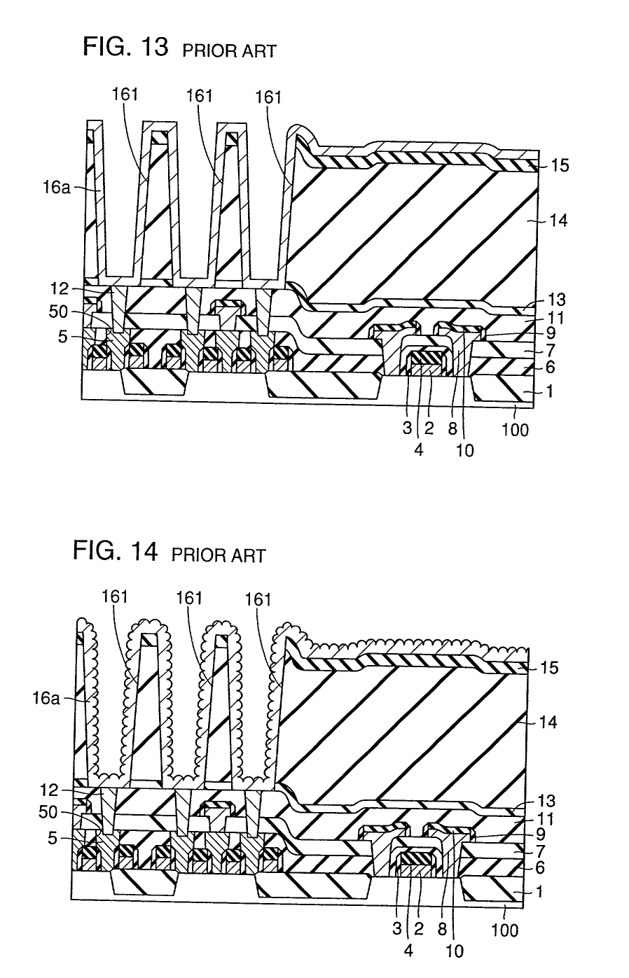

Referring to FIG. 8, an insulating interlayer 19 is deposited and its surface is polished by CMP.

After that, the insulating interlayer 20 is deposited and a contact hole 21 is formed. Since the insulating interlayer 15 of a low etching rate does not exist in a region for forming the contact hole 21, etching for forming the contact hole 21 is easily carried out. Consequently, poor opening does not occur, so that the yield is improved.

It should be understood that all the embodiments disclosed here are illustrative and not restrictive. It is intended that the scope of the invention is not limited by the above description but is defined by the claims, and that all changes are included in the scope of claims or equivalence of such meets and bounds.

As described above, in the semiconductor device according to the first aspect of the invention, a step extending from the memory cell portion to a peripheral circuit portion can be reduced. Consequently, poor opening in etching can be prevented. Moreover, the semiconductor device having excellent characteristics can be realized.

In the case where the antireflection film is used as the insulating interlayer, the transfer margin in the photography process for forming the storage node is improved.

In the method of fabricating a semiconductor device according to a second aspect of the invention, poor opening of a contact hole in a step inclined portion does not occur, so that deterioration in yield can be prevented. The capacity of a capacitor can be also prevented from being reduced, and the refresh characteristic can be improved.

In the case of forming the insulating interlayer by the antireflection film, the transfer margin is improved in the photography process for forming the storage node.

In the method of fabricating a semiconductor device according to a third aspect of the invention, the insulating interlayer of a low etch rate does not exist. Consequently, etching for forming a contact hole can be easily performed, poor opening does not therefore occur, and the yield is improved.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device including:
a semiconductor substrate having a memory cell region in which a memory cell is to be formed and a peripheral circuit region in which a peripheral circuit is to be formed;
a first insulating interlayer provided on said semiconductor substrate so as to cover said memory cell region and said peripheral circuit region; and
a second insulating interlayer provided on said first insulating interlayer,
wherein an interface between said first and second insulating interlayers is parallel to the surface of said semiconductor substrate.

2. The semiconductor device according to claim 1, wherein said second insulating interlayer is formed by an antireflection film.

3. A method of fabricating a semiconductor device, including:
a step of preparing a semiconductor substrate having a memory cell region in which a memory cell is to be formed and a peripheral circuit region in which a peripheral circuit is to be formed;
a step of forming a first insulating interlayer on said semiconductor substrate so as to cover said memory cell region and said peripheral circuit region;
a step of polishing the surface of said first insulating interlayer;
a step of forming a second insulating interlayer on said first insulating interlayer; and
a step of opening a hole penetrating said first and second insulating interlayers in said memory cell region and forming a cylindrical capacitor in the hole.

4. The method of fabricating a semiconductor device according to claim 3, wherein an antireflection film is used as said second insulating interlayer.

5. The method of fabricating a semiconductor device according to claim 3, wherein the step of forming said cylindrical capacitor includes:
a step of forming a hole penetrating said first and second insulating interlayers in said memory cell region;
a step of forming a first conductive layer for forming a lower electrode of a capacitor on said second insulating interlayer so as to cover side walls and a bottom face of said hole;
a step of forming a capacitor lower electrode by etching back said first conductive layer to expose a surface of said second insulating interlayer;
a step of covering the surface of said capacitor lower electrode with a capacitor insulating film;
a step of forming a second conductive layer for forming a cell plate electrode, which is buried in said hole so as to be in contact with said capacitor lower electrode via said capacitor insulating film; and
a step of forming a cell plate electrode by patterning said second conductive layer.

6. The method of fabricating a semiconductor device according to claim 5, wherein a silicon oxide film to which B or P is doped is used as said first insulating interlayer, and
an SiN film is used as said second insulating interlayer.

7. A method of fabricating a semiconductor device, including:
a step of preparing a semiconductor substrate having a memory cell region in which a memory cell is to be formed and a peripheral circuit region in which a peripheral circuit is to be formed;
a step of forming a first insulating interlayer on said semiconductor substrate so as to cover said memory cell region and said peripheral circuit region;
a step of polishing the surface of said first insulating interlayer;
a step of forming a second insulating interlayer on said first insulating interlayer;
a step of forming a hole penetrating said first and second insulating interlayers in said memory cell region;
a step of forming a first conductive layer for forming a capacitor lower electrode on said second insulating interlayer so as to cover side walls and a bottom face of said hole;
a step of forming a capacitor lower electrode by etching back said first conductive layer to expose a surface of said second insulating interlayer;
a step of covering the surface of said capacitor lower electrode with a capacitor insulating film;
a step of forming a second conductive layer for forming a cell plate electrode, which is buried in said hole so as to be in contact with said capacitor lower electrode via said capacitor insulating film;
a step of forming a cell plate electrode by selectively etching said second conductive layer and removing said second insulating interlayer in a portion where the cell plate electrode is not formed by etching; and
a step of forming a third insulating interlayer over said semiconductor substrate so as to cover said cell plate electrode.

8. The method of fabricating a semiconductor device according to claim 7, wherein a silicon oxide film to which B and P is doped is used as said first insulating interlayer, and
an SiN film is used as said second insulating interlayer.
